(19) United States
(12) Patent Application Publication
(10) Pub. No.: US 2015/0355245 A1
(43) Pub. Date: Dec. 10, 2015

(54) SYSTEM AND METHOD FOR MONITORING AN ELECTRICAL NETWORK

(71) Applicant: CIRCUITMETER INC., Ajax (CA)

(72) Inventor: Michael ORDANIS, Ajax (CA)

(73) Assignee: CIRCUITMETER INC., Ajax, ON (CA)

(21) Appl. No.: 14/763,361

(22) PCT Filed: Jan. 24, 2014
(86) PCT No.: PCT/CA2014/000043

§ 371 Date: Jul. 24, 2015

Related U.S. Application Data
(63) Continuation-in-part of application No. 13/749,896, filed on Jan. 25, 2013.

(51) Int. Cl. G01R 21/133; G01R 31/42

(52) U.S. Cl. CPC G01R 21/133; G01R 31/42

(57) ABSTRACT

An energy monitoring system which in preferred embodiments employs at least one nodal junction receiving and creating data by analog to digital conversion from a plurality of local node sensors. Data accumulated by the nodal junction is used for analysis of wave patterns to detect anomalies in the local electrical network and/or loads connected to the local electrical network. Anomalies can be detected in various ways, including: comparison of data with historical data acquired from the local node sensors; comparison of data with known wave pattern profiles for similar loads; and comparison of data with data acquired from local node sensors at other locations. Thus, the accumulation of data in the system of the invention provides the ability to perform comparative analysis to a baseline or standard, and also the ability to perform comparative analysis at an enterprise level across different target locations.

### FIELD OF THE INVENTION

This invention relates to an energy monitoring systems for measuring and recording the electrical energy consumed by one or more loads.

### BACKGROUND OF THE INVENTION

It is well known in the art that devices can be made to measure and record the electrical energy used by a load and some of these devices with further enhancements can be made to measure and record the current harmonics created by the load. There are a number of patents which reveal devices which can measure the energy consumption and current harmonics of loads, both individual and grouped. These prior art devices are bulky, expensive and tend to be limited with respect to the number of loads that can be monitored by a single device, frequently requiring considerable expertise in their implementation and use. Many of these prior art devices are only able to measure just total electrical energy, total gas or total water consumed at the premises.

The analysis of data generated by such systems is also limited. Electrical network data analysis conventionally utilizes internal data generated by the system. Such analyses do not take into account data from external sources that might affect electrical energy usage analyses such as weather data, data relating to alternative electrical energy sources, and data relating to bi-products of energy supply and usage such as greenhouse gas production, for example.

Additionally, the manner in which the data is presented to the customers of such systems (for example electrical power utilities, commercial building owners etc.). Different organizations and institutions can use energy-related information for disparate purposes, and conventional interfaces do not readily lend themselves to optimal data utilization by customers.

It would accordingly be advantageous to provide a system and method for monitoring an electrical network that overcomes one or more of these limitations.

### BRIEF DESCRIPTION OF THE DRAWINGS

In drawings which illustrate by way of example only a preferred embodiment of the invention,

FIG. 1A is a schematic view of a first system according to the invention.

FIG. 1B is a schematic view of a further system according to the invention.

FIG. 2 is a schematic view of one embodiment of a nodal junction according to the invention.

FIG. 3 is a schematic view of a further system according to the invention.

FIG. 4 is a schematic view of a further system according to the invention.

FIG. 5 is a schematic view of a further embodiment of a nodal junction according to the invention.

FIG. 6 is a schematic diagram of an embodiment of a voltage sensor circuit utilizing a resistor divider network providing optional safety features connected to a nodal junction.

FIG. 7 is a schematic diagram of an embodiment of a voltage sensor circuit utilizing potential transformers to isolate the load from the sensor outputs.

FIG. 8 a schematic diagram of a further embodiment of a sensor circuit connected to a nodal junction.

### DETAILED DESCRIPTION OF THE INVENTION

The various embodiments of the system of the invention address one or more of the above disadvantages and provide a versatile, safe and secure method of collecting, transferring and displaying electrical supply and usage data and parameters derived from the data. It will be appreciated that not every advantage of the invention applies to every embodiment described herein.

The invention thus provides a system for monitoring electrical variables of at least one AC electrical load wired to at least one breaker pole connected to a phase of an AC electrical source, comprising at least one ampere sensor configured to produce an output analog signal proportional to the amperes in at least one electrical load conductor, comprising an inductor having at least one complete electrical turn in inductive communication with said load conductor, at least one nodal junction configured to calculate at least one electrical measurement from the signal received from the at least one sensor, and configured to create at least one data string comprising at least one electrical measurement, and a network communication circuit configured to transmit data to a network server, and at least one network server configured to receive data strings from the at least one nodal junction controller, to transmit a reply data string to the at least one nodal junction controller for each set of one or more data strings received, each reply string containing acknowledgement data for the set of one or more data strings to which the reply relates, and optionally data to control and change the functionality of the at least one nodal junction controller via an optional command string returned with said reply string.

The invention further provides a method for securely collecting and storing electrical variables associated with at least one AC electrical load or electrical power source, comprising the steps of: a. receiving a signal from at least one sensor having inputs connected to a supply circuit conductor of the AC electrical load or source, b. calculating at least one electrical measurement derivable from the at least one sensor, c. providing an encryption algorithm and a encryption key for encrypting the at least one electrical measurement, and d. encrypting and transmitting the at least one electrical measurement to a network server accessible by one or more parties possessing said encryption key.

The invention further provides a method for analyzing electrical measurements from AC electrical loads or AC electrical sources comprising the steps of: a. receiving a signal from at least one sensor having inputs connected to a supply circuit conductor of at least one of the AC electrical load or the AC electrical source, or both, b. calculating electrical measurements derivable from the signal received from the at least one sensor, c. storing said electrical measurements in a data store in association with respective timestamps, d. querying said electrical measurements along with data from at least one external source comprising one or more of: weather data; data representing the percentage that the amount of electrical energy relating to the electrical energy measurements is to all electrical energy produced from electrical energy sources; and data representing amounts of greenhouse gases released into the atmosphere for each Watt Hour of electrical energy produced from said energy sources, and e. displaying the results in the form of a pivot table report.

Although described below primarily in the context of energy consumed by an AC electrical load, the invention can be applied to any AC load that consumes electrical energy and/or to an AC source that produces electrical energy.

The invention provides an energy monitoring system which in preferred embodiments employs at least one nodal junction 20 receiving data in the form of current signals from a plurality of local node sensors 12. The current signals generated by local node sensors are either alternating current (AC) or direct current (DC) and are typically in the 0-100 mA range, which are converted to millivolt levels and then sampled by an analog to digital converter (ADC) contained within the nodal junction to create data points for further analysis. Examples of AC sensors include current transformers (CT) to measure current and potential transformers (PT) to measure voltage. Examples of DC sensors include gas and water volume pulse generators, pressure sensors, temperature sensors, airflow sensors and CO₂ level sensors. Data accumulated by the nodal junction is used for analysis of wave patterns to detect anomalies in the local electrical network and/or loads 2 connected to the local electrical network. Anomalies can be detected in various ways, including: comparison of data with historical data acquired from the local node sensors; comparison of data with known wave pattern profiles for similar loads 2; and comparison of data with data acquired by local node sensors at other locations. Thus, the accumulation of data in the system of the invention provides the ability to perform comparative analysis to an historical profile, or to a baseline or standard developed from known wave pattern profiles for similar loads 2; comparison of data with known wave pattern profiles published as regulatory or standards data for profiles with similar loads; and/or networks; and also the ability to perform comparative analysis at an enterprise level across different target locations.

Any AC powered electrical device or circuit when in use or operation generates a “field harmonic”, or wave pattern. The wave pattern is more pronounced in nonlinear loads (i.e. loads that draw current with a waveform that is not the same as the waveform of the supply voltage). Examples of non-linear loads include: Welding machines, are furnaces, induction furnaces, rectifiers, variable-speed drives for asynchronous or DC motors, UPSs, computers, photocopy machines, fax machines, television sets, microwave ovens, fluorescent lighting, LED lighting and devices involving magnetic saturation such as transformers. The negative effects of certain waveforms can be (a) increases in energy costs and (b) premature aging of equipment. The present invention employs local node sensors to collect data from any electrical device or circuit connected to individual breakers at the target location and communicates the data, via telemetry transmission, to a collection server in order to compute a Discrete Fourier Transform (DFT) using a “Fast Fourier Transform” (FFT) algorithm that will establish the wave pattern or field harmonic for the specific load 2 or circuit from which the data has been collected.

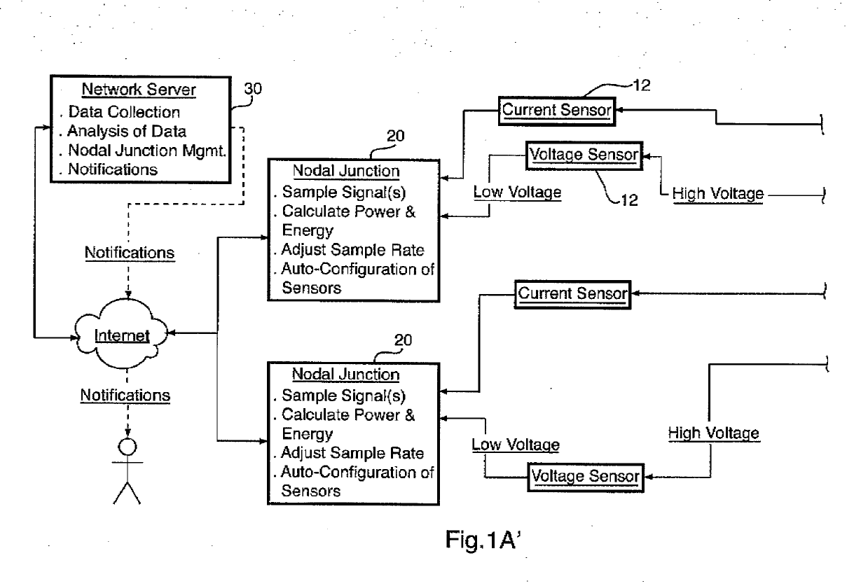

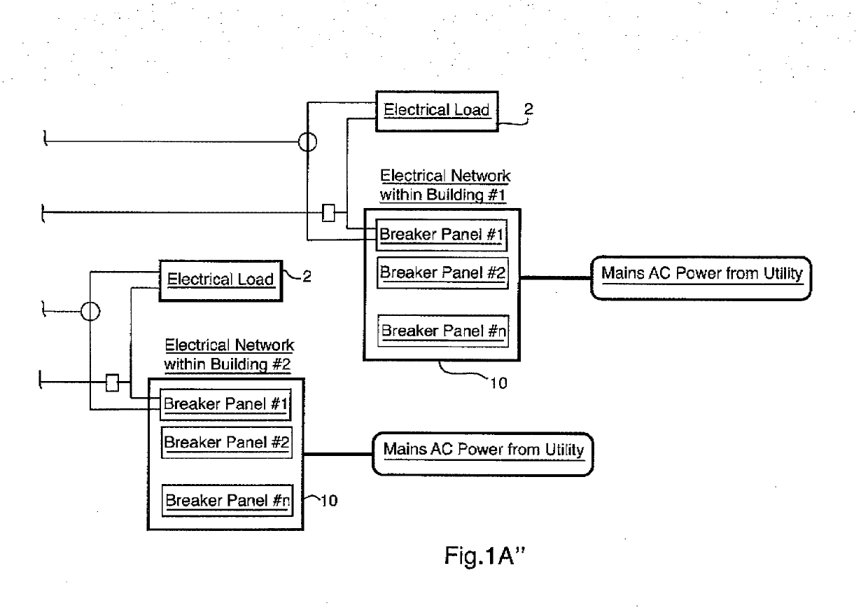

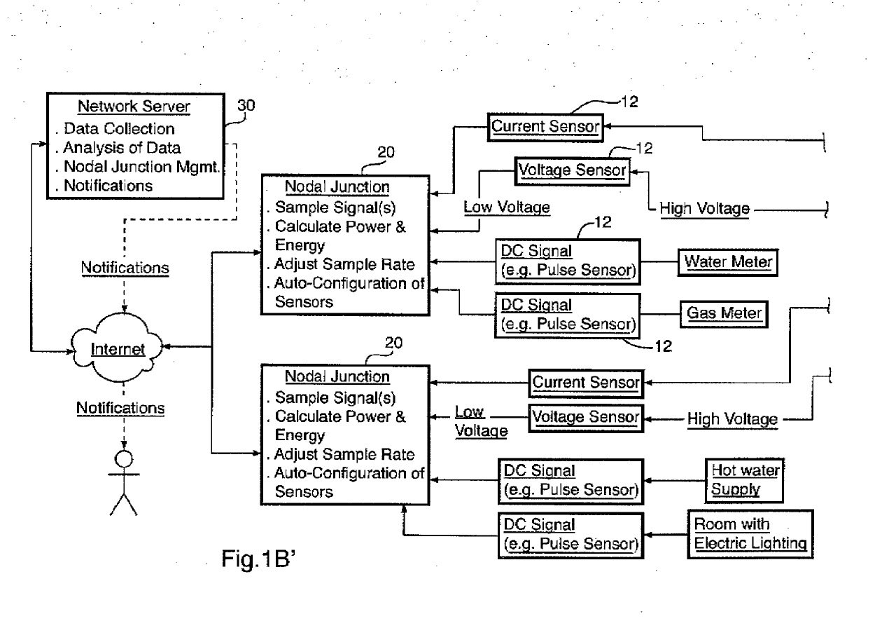

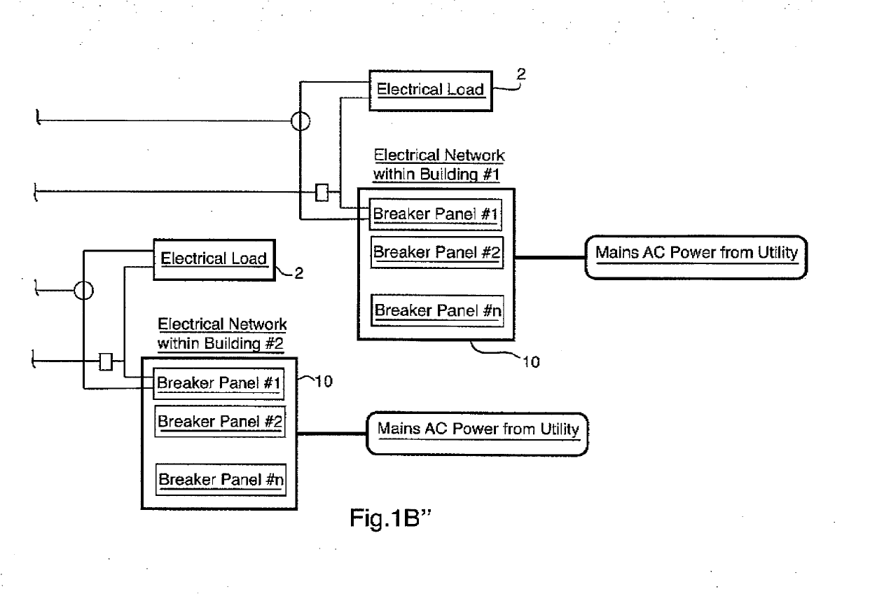

FIG. 1 illustrates a system according to the present invention, by way of example, showing two target locations 10 of a potentially unlimited number of target locations. The continuous collection of telemetry data by this system over time, and in the preferred embodiments over different locations, allows for a comparative analysis of wave patterns to detect anomalies.

In one preferred embodiment, prior to installation of the system of the invention at a target location a baseline DFT pattern for operation standards for the electrical network can be established based on other locations having a similar network and/or comparable loads 2 and circuits, or on specific loads 2 in a circuit. A DFT pattern established based on electrical network and load 2 operation can be compared to this standard or baseline in ongoing sampling during operations, to detect anomalies in a load 2 and/or circuit. Such anomalies can be detected prior to an actual fault condition, thus providing the end user with dynamic analysis for preventative maintenance of loads 2 and electrical circuits, as well as ongoing analysis that can allow an end user to optimize loads 2 and circuits to improve efficiency and electrical consumption levels.

For example, an air handling unit with bad or worn bearings, belts or pulley on its blade assembly will require greater power consumption or a power surge to move the blade to a desired RPM level. The FFT comparison of real-time data from the faulty air conditioner with data acquired from a similar model or capacity of air conditioner will show a spike or electrical surge or variation in the wave pattern which can be analyzed and corrective action taken. Similarly, in a compressor or pump with worn seals or valves the motor must work harder or for a longer time to maintain pressure against loss through the seals. The change of DFT from the known baseline or standard would be indicated in the wave pattern, and corrective action and/or a more detailed analysis of the problem load 2 can be initiated.

The system of the invention monitors the electrical variables of at least one AC electrical load or ac electrical source wired to at least one breaker pole via a load conductor. Typically each such breaker pole is located within an electrical distribution enclosure, and connected to one of a set of voltage phase elements which may comprise a single element A, double elements A, B, or polyphase elements A, B, C. Each such breaker pole is uniquely numbered within the enclosure.

In an example involving a circuit, a simple electrical outlet or branch circuit with multiple outlets which is overloaded, for example with multiple power bars connected to loads 2, would show an increase or surge in load 2 levels as the electrical devices connected to the power bars are activated. Such devices may be able to operate on lower power setting, and as such would not cause the circuit breaker to trip; but as the connected devices need more power, surges to the limit of the circuit will be indicated in the DFT pattern as power spikes, even if the duration of the spikes is too short to trip the breaker. Comparative analysis of DFT wave patterns—either with historical patterns from that location or with baseline standards set by data accumulated from a number of locations—will show the spikes and action can taken to correct the overload on the outlet and associated circuit.

The basic system comprises at least one node sensor 12, preferably a plurality of node sensors 12 as shown, disposed at the target location 10. The node sensors 12 may for example include any number of electrical sensors, heat sensors, vibration sensors and/or pulse sensors, depending upon the particular network or equipment being monitored. In the preferred embodiments the system comprises at least one ampere sensor configured to produce an output analog signal used in the process of measuring the amperes in one of the AC electrical load conductors, comprising an inductor having at least one complete electrical turn in inductive communication with the load conductor, and at least one voltage sensor configured to produce an output analog signal used in the process of measuring the voltage difference between one voltage phase element and a common reference point shared by all voltage phase elements (in double or multiphase systems) such as a neutral wire.

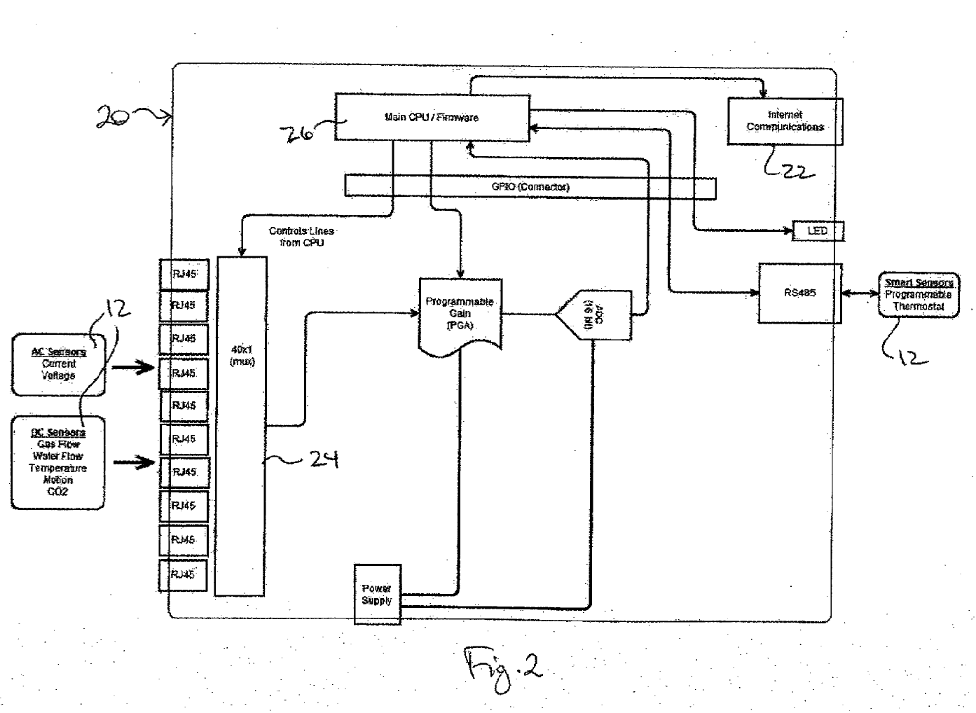

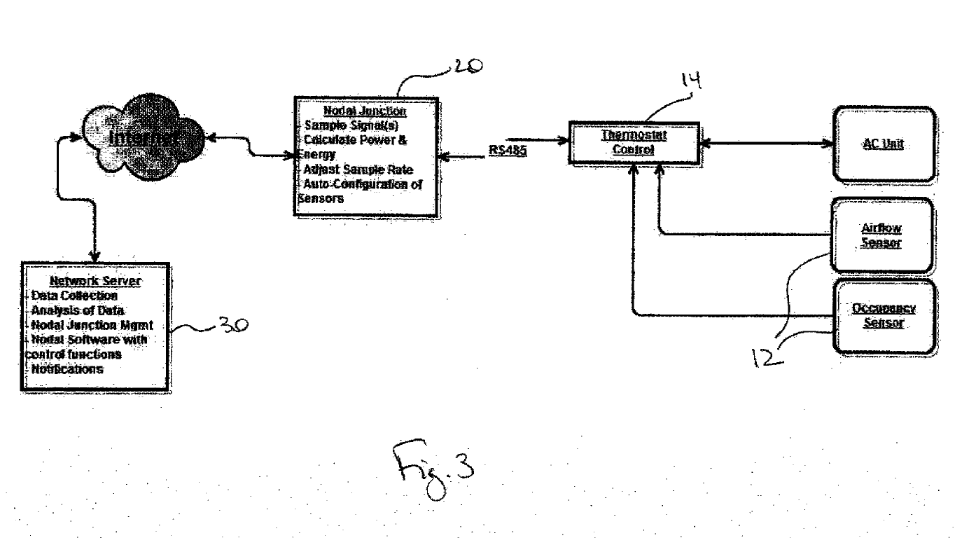

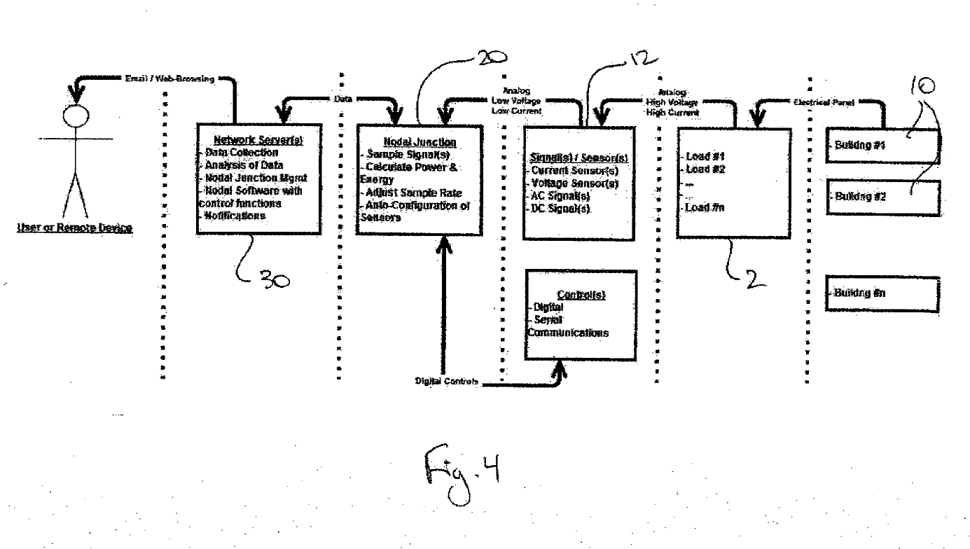

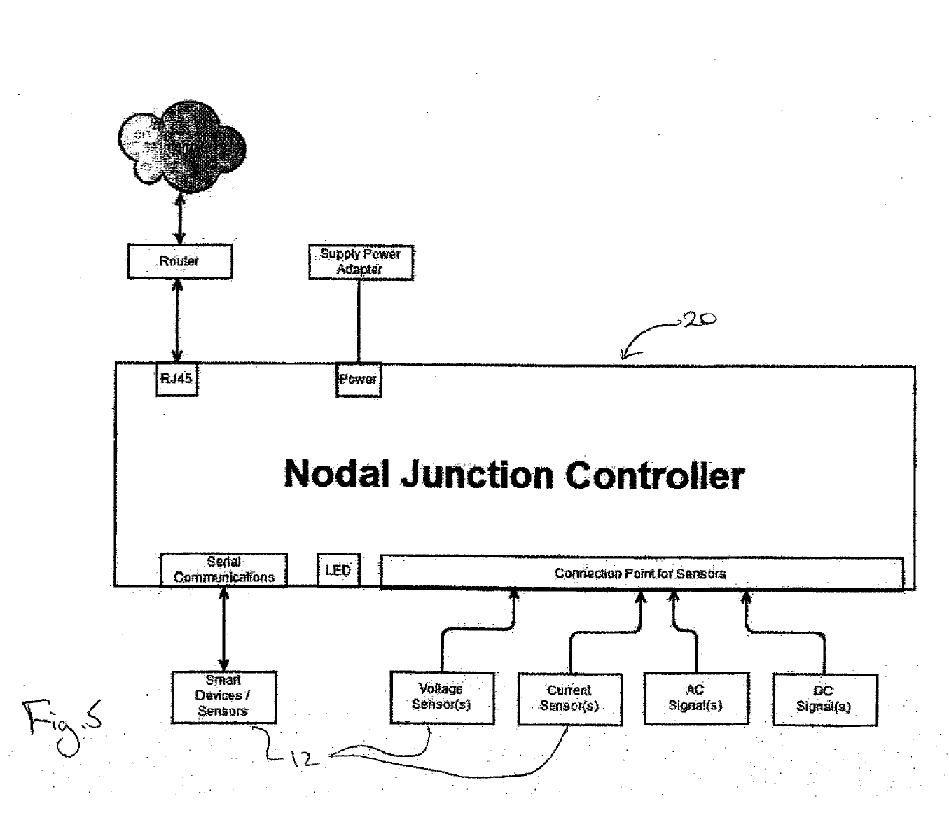

For example, electrical sensors 12 such as current sensors and voltage sensors may be used to monitor circuits in the electrical network; heat sensors can be used to monitor motorized devices and other devices which might be subject to overheating due to a malfunction, heating systems, furnaces and the like; vibration sensors can be used to monitor compressors, motorized devices and other devices which have reciprocating or rotational components that produce a consistent vibration pattern, as shown in FIG. 3; and pulse sensors may be used to monitor pulse signals from incremental counters for measuring, for example, gas feed for heating/air conditioning or other gas-fed devices, and air flow and/or water flow rates, as shown in FIG. 3.

The system may comprise at least one sensor 12 designed to provide at least one signal representative of a non-electrical measurement, for example the motion of an object in a space, speed of an object, mass of an object, volume and direction of fluid flowing, temperature, humidity, pressure, air quality, percentage content of a gaseous substance, radiation level, pH of a liquid, level of a fluid in a tank, etc. These types of sensors 12 are associated with a sampling channel configuration string containing information which indicates a connection of a non-electrical sensor to at least one of the sampling channels. The nodal junction 20 is configured to concurrently sample at least one non-electrical sensor attached to any sampling channel, and to make at least one non-electrical measurement on at least one sampling channel simultaneously while making measurements using current and voltage sensors on other sampling channels. The nodal junction 20 may be further configured to create data strings which further comprise of root mean square values of arrays of sample data from non-electrical sensors 12.

In the preferred embodiments the node sensors 12 are linked with a nodal junction 20 communicating the data acquired from the node sensors 12 to a data processing device such as a server 30, to thus capture all the reported data (including FFT input data) and store it on the server 30. The end user analysis is performed at the server 30, which contains the comparative data (historical, baseline, etc. as available).

The system relays data through at least one nodal junction 20, preferably a plurality of nodal junctions 20, each comprising at least one microcontroller circuit 60, and at least one timer circuit for applying a timestamp to transmissions to at lease one network server 30, as described below. The nodal junction microcontroller 60 is pre-programmed with control firmware, and assigned a unique ID, for example a serial number. The nodal junction 20 further comprises at least one analog to digital converter (ADC), volatile memory and non-volatile memory.

In the preferred embodiment the nodal junction 20 is programmable, and can be programmed by the server 30 dynamically to extract specific select data points, and/or control all local node sensors 12 to extract (or filter) selected information. The nodal junction 20 consolidates the data from the various node sensors 12, thus greatly reducing bandwidth requirements, and transmits the data to the server 30 (which in turn may consolidate data from multiple nodal junctions 20). Preferably where the nodal junction 20 is dynamically programmed for specific data collection, it can also isolate any of the local node sensors 12 at the target location to collect specific data points different from the other local node sensors 12.

This can be accomplished by connecting each sensor 12 to a separate sampling channel of the nodal junction 20, each channel comprising a unique sampling channel ID (for example an alphanumeric identifier). The nodal junction 20 further comprises a network communications module 22 configured to transmit data strings to the network server 30.

When the server 30 receives and records the collected data, it can function in a single-user or customer mode, or can perform analysis across an entire enterprise network. This provides a comparative profile over a large number of like networks and/or loads 2, which benefits users because the larger data pool provides profiles for a greater variety of networks and loads 2, and more data from which to establish norms and baselines within each category of network and load 2. Thus, in one embodiment users can “opt in” to participate in data-sharing based on the pool of data acquired from all users of the system, for the benefit of all participating users.

Thus, the comparative analysis can be performed not just on end user data, but on all of the enterprise (or all users') data points. In this fashion an anomaly can be detected via an historical comparison, but also by comparison to all circuits across the enterprise for each data point for like devices. This enables full enterprise data collection and analysis in the preferred embodiments of the invention, and thus allows each user to benefit from other installations connected to the enterprise server.

By way of non-limiting examples, analysis of DFT wave patterns, amperage, power levels and energy consumed the server 30 can indicate a fault condition by initiating warnings or alarms before equipment being monitored reaches a fail-point or an inefficient mode of operation, by comparison to a standard or baseline which allows the server 30 to detect anomalous behaviour from any load 2 or circuit. This provides an opportunity for preventative analysis and action (as opposed to post-hoc fail-point analysis). In the preferred embodiments this function is robust and flexible, so that warning parameters or anomaly range selection can be entered by the user or system administrator, and changes at any time and the nodal junction 20 and local node sensors 12 at the target location can be dynamically modified for the newly selected ranges.

The node sensors 12 would typically be sampled at standard sampling rates (e.g. 3 to 4 ksps), and from the sampling of electrical performance in loads 2 and circuits are able to collect the necessary component information to be analyzed through an FFT and the resultant wave pattern. Preferably each node sensor 12 has the capability of sampling at a much higher sampling rate in specific situations, the nodal junction 20 being capable of dynamically increasing (or decreasing) the sampling rate of one or more node sensors 12 as needed to allow for flexible analysis and patterning of a given electrical circuit or device. The node sensors 12, being distributed about the target location 10, monitor many electrical circuits and loads 2 and provide data from each for FFT analysis.

The nodal junction 20, illustrated in FIG. 2, is a collection point for data sampled from the local node sensors 12. The nodal junction 20 collects information from local node sensors 12, preferably for multiple services (for example electrical, water and gas), and passes the accumulated sensor information, to the network sever 30 for data storage and analysis. The nodal junctions 20 are preferably capable of collecting information from multiple local node sensors 12, for example through multiplexer 24, and accumulating the data into a single packet or small number of packets for transmission to the server 30 via communications module 22, for example over the Internet as shown in FIG. 1, thus reducing the total bandwidth required to transfer data from multiple collection points. In the preferred embodiment calculations are performed on the sensor data at the nodal junction 20, generating derived values that can then be transmitted to the network server 30 instead of the raw data, resulting in considerable reduction in amount of data transmitted. Also, in the preferred embodiment an encryption algorithm is embedded in the nodal junction 20 and a private key is provided to users of the system. This permits the electrical measurements (including derived electrical measurements) to be encrypted and securely transmitted to the network server 30 for dissemination to parties possessing said private encryption key. The nodal junctions 20 and network servers 30 preferably utilize at least one common authentication algorithm and authentication key, and at least one common encryption algorithm and encryption key.

The nodal junction 20 may compute an original hash string of every data string it transmits, using its common authentication algorithm and authentication key, and transmit every data string with its original hash string. The network server 30 will re-compute the hash string of every data string it receives, using its common authentication algorithm and authentication key, and ignore any data string when the re-computed hash does not equal the original hash string. The network server 30 may compute one original hash string for every reply string and command string pair, and transmit every reply string and command string pair with its original hash string. The nodal junction 20 in turn re-computes the hash string of every reply string and command string pair it receives, using its common authentication algorithm and authentication key, and ignore any reply string and command string pair when the re-computed hash does not equal the original hash string.

The nodal junction 20 may await a reply from the network server 30 before sending further strings. The network server 30 will reply to a set of one or more strings from the nodal junction 20 with, amongst other data, acknowledgement data. The nodal junction 20 preferably awaits the acknowledgement data from the network server 30, acknowledging the receipt and processing of the set of one or more strings received from the nodal junction 20, before sending further strings to the network server 30.

In the preferred embodiment the nodal junction 20 preferably uses IP packets in the transmission of data strings to a network server 30, to encode data strings into such IP packets using the User Datagram Protocol prior to transmitting them to the network server, to receive IP packets from the network server 30, and to decode reply strings and command strings from such IP packets using the User Datagram Protocol. The network server 30 is in turn configured to receive IP packets from each nodal junction 20, to decode data strings from such IP packets using the User Datagram Protocol, to use IP packets in the transmission of reply strings and command strings to a nodal junction 20, and to encode said reply strings and command strings into such IP packets using the User Datagram Protocol prior to transmitting them to a nodal junction 20. In this way data can be transmitting to the network server 30 without the requirement of “opening a port” on the firewall at the target location 10.

In some embodiments the collection and transfer to data by the nodal junction 20 comprises assigning an ID (e.g. a serial number) to the nodal junction microcontroller 60, and assigning an ID (e.g. sensor number) to each sensor 12 corresponding to the sensor channel number in the nodal junction 20 to which the sensor outputs are connected. The electrical measurements derived from a single sensor 12 are encrypted using a public encryption algorithm and the embedded private encryption key. Data strings are created within the nodal junction 20, which may comprise one or more of the encrypted electrical measurements, the sensor number, the serial number of the nodal junction 20, a timestamp indicating when the electrical measurements were taken, and an incrementally increasing sequence number.

The data strings are transmitted to the network server 30, and the network server in turn acknowledges the receipt of data strings by transmitting a reply string to the nodal junction 20, preferably one reply string for every data string received from the nodal junction, each reply string including the timestamp and sequence number that was contained in the associated received data string, as well as the ID of the nodal junction from which the received data string originated. The received data strings are preferably appended to individual flat files stored with the network server, in the preferred embodiment one flat file for each serial number/sensor number pair, and the flat file is named using a naming convention such that the serial number and sensor number appear in the flat file name, for example {SerialNumber}.{SensorNumber}.csv.

In the preferred embodiment the data strings from the nodal junction 20 are packetized for transmission to the network server 30 in an IP protocol (or other suitable network protocol), at fixed timed intervals. Similarly, the reply strings from the network server 30 are packetized for transmission to the nodal junction 20. Optionally a unique command string is provided along with (or within) the reply string for the purpose of modifying the behaviour of the nodal junction 20. Such command strings may comprise commands which modify the time interval used by the nodal junction 20 to transmit data strings to the network server 30, and/or commands to select a subset of available electrical measurements transmitted to the network server, by way of non-limiting example, preferably using the User Datagram Protocol. Command strings may be stored in a database and maintained and modified via a graphical user interface accessible to authorized parties.

Command strings may by way of non-limiting example comprise one or more of the following: an instruction to load new control firmware, an instruction to reload configuration parameters, an instruction to change the frequency at which data strings are to be transmitted from the nodal junction microcontroller 60; an instruction to modify the sampling channel subset table; an instruction to change the frequency at which each sampling channel is to be sampled; an instruction to modify the breaker pole to voltage phase element lookup table; an instruction to modify the sampling channel to breaker pole lookup table; an instruction to change the frequency at which arrays of voltage sample data and arrays of amperage sample data are to be transmitted to the network server for FFT processing; an instruction to change the minimum value of RMS amperage that must be present before transmitting arrays of amperage sample data to the network server; and/or an instruction to reboot and return to a power on state.

The nodal junction 20 is configured to change its functionality upon receipt and interpretation of any command string included with a reply string. Such changes may by way of non-limiting example comprise one or more of the following: loading new control firmware, reloading configuration parameters, changing the frequency at which data strings are transmitted to a network server; changing the subset of sampling channels to sample by modifying the sampling channel subset table; changing the frequency at which each sampling channel is to be sampled; changing the assignment of breaker poles to voltage phase elements by modifying the breaker pole to voltage phase element lookup table; changing the assignment of sample channels to breaker poles by modifying the sample channel to breaker pole lookup table; changing the frequency at which arrays of voltage sample data and arrays of amperage sample data are transmitting to the network server for FFT processing; changing the value of the minimum RMS amps that must be present before arrays of amperage sample data are transmitted to the network server for FFT processing; and/or resetting the nodal junction 20 to its power on state.

The nodal junction 20 may be further configured to temporarily change its default functionality upon receipt and interpretation of a command string. Such temporary changes in functionality may by way of non-limiting example comprise one or more of the following: halting the scanning of sampling channels listed in the sampling channel subset table; creating an array of higher resolution samples by sampling a single channel at the maximum sampling rate of its associated analog to digital converter, where the size of the said array and single channel number is specified in the command string; and/or returning to its default sampling behaviour after transmitting the array of finer resolution samples to the network server 30.

Permissions may be set, for example using an application programmers interface (API), to permit authorized parties to perform tasks such as downloading flat files from the network server 30 (by specifying the serial number of the nodal junction 20 and sensor number associated with the AC electrical load of interest); modifying the time interval between successive transmission of IP packets containing data strings, and/or selecting a subset of available electrical measurements to be including in the data string. The system of the invention may also provide instructions to the user of the API in relation to decryption of the data strings after downloading using the public encryption algorithm and the private encryption key in their possession. The system of the invention may also provide one or more password protected application programmers interfaces, configured to enable third parties to query the database and to use the query results to create new products and services.

The nodal junctions 20 can be stacked into an array, as shown in FIG. 1, thus handling a greater number of local node sensors 12 and concentrating the accumulated data for the server 30. The nodal junction 20 preferably has flexible firmware control resident in CPU 26 which, based on data received and analyzed, can be dynamically changed by the server 30. Examples of dynamic changes are: sampling rates on any given local node sensor 12 can be changed for a more thorough or comparative analysis; changing calibration values of the various gain stages can be fine tuned to compensate for aging components in the signal chain, and special treatment of data from different models of sensors of the same type.

While the server 30 captures and archives historical information from all (active) node sensors 12 and nodal junctions 20, in the monitoring of electrical equipment, heating, air conditioning, generators and other such devices in any given environment, maintaining an accurate history is useful for comparative or spot curve analysis, and can be used to isolate specific equipment or to look at the environment at the target location 10 as a whole. The application software residing in the server 30 is preferably designed to provide the user with detailed information on all devices within a specific environment, while at the same time providing the user with the flexibility to isolate specific devices or time slices in that environment. Such flexible application software is designed to provide the user with detailed information while at the same time providing the greatest flexibility.

The architecture of the overall system is thus a server-controlled information service, which can be applied to some or all metered devices in any target location 10, effectively serving as a ‘top down’ control system to provide the end user maximum flexibility and control to monitor all loads 2 and circuits being monitored in the target location or any portion thereof. In some embodiments the server 30, or the nodal junction 20, may provide control signals to adjust the environment at the target location 10, for example as shown in FIG. 3 in which the thermostat 14 monitoring ambient air temperature can be configured and/or controlled by the server 30 (via the nodal junction 20) to adjust the air temperature in response to a deviation outside an acceptable range.

When the system is set up a standard for monitored devices or benchmark may set, providing the server with a baseline on which to base its programmed analysis. As the server collects data for analysis, it can automatically compare selected data with a benchmark value established by the baseline, and if the data does not match the benchmark (within a user-selected range or allowable deviation), the system can be programmed to notify the user by alert (for example, a text message or email), of the variance or anomaly detected so the user can take immediate corrective action.

In addition to the internal data collected and stored by the network server 30, the system of the invention may analyze electrical measurements derived from the sensors 12 taking into account data from at least one external source. External sources may for example comprise weather data, percentage data relating energy consumption of monitored loads (or sources) to the total electrical energy produced from sources such as hydro, nuclear, coal, natural gas, wind, solar, bio-fuel etc., the total amount of greenhouse gases (by gas type) released into the atmosphere for each Watt Hour of electrical energy produced from sources such as hydro, nuclear, coal, natural gas, wind, solar, bio-fuel etc. The system allows users to query both the stored electrical measurement data and such external data, preferably using a customizable and configurable user interface.

The network server 30 may for example be configured to access to at least one remote database containing weather information about at least one geographic region comprising air temperature and/or humidity; and/or to access to at least one remote database containing information about at least one building structure comprising one or more of the number of floors, dimensions of each floor, number of suites on each floor, dimension of each suite, size of windows in each suite, and/or fixed mechanical systems; and to access to at least one remote database containing information about tenant and occupancy loads of at least one building comprising one or more of number of employees and/or number of customers. The network server 30 may also be configured to analyze from nodal junctions 20 and combine said data with data from other local or remote databases to create a set of key performance indicators comprising one or more of the average energy consumed by each building for each degree of outside temperature; the average energy consumed by each building per square unit of floor area; the average energy consumed by each building per cubic unit of building volume; the average energy consumed by each tenant in each building; and/or the average energy consumed by each occupant in each building. Query results can be returned in the form of a C×R summarization table with C columns and R rows (also known as a “pivot table” report). By way of example only, a pivot table can be generated by:
a. creating a primary list of data point types comprising any or all of the following:
   i. potential in volts, and
   ii. current in amps, and
   iii. real power in watts, and
   iv. reactive power, watts reactive, and
   v. energy import in watt hours, and
   vi. energy export in watt hours, and
   vii. power factor (no units).
b. creating a secondary list of data point types comprising any or all of the following:
   i. country id, and
   ii. state/province id, and
   iii. region id, and
   iv, a city/town id, and
   v. building id, and
   vi. building floor id, and
   vii. building section id, and
   viii. building section type id, and
   ix. building elevator level id, and
   x. electrical panel/enclosure id, and
   xi. tenant id, and
   xii. tenant type id, and
   xiii. hour of day, and
   xiv. time of use id, and
   xv. day of the week, and
   xvi. voltage phase id, and
   xvii. outside air temperature, and
   xviii. outside humidity, and
   xix. equipment id, and
   xx. equipment type id.
c. creating a list of math function operators comprising any or all of the following:
   i. sum( ), and
   ii. average( ), and
   iii. minimum( ), and
   iv. maximum( ), and
   v. standard deviation( ), and
   vi. and count( ).
d. selecting a data point type from the list of primary data point types, and
e. selecting an X-axis-group-by data point type from either the primary or secondary list of data point types, and
f. selecting an Y-axis-group-by data point type from either the primary or secondary list of data point types, and
g. selecting a math operator, and
h. selecting a date/time range with start and stop date/times, and
i. creating at least one include_only_if_filters, where the at least one include_only_if_filters comprises of:
   i. a data point type from the list of secondary data point types, and
   ii. a set of required matching values.
j. creating a 2 dimensional table of numerical values (2D-table) with no initial rows nor columns, and
k. creating a subset of data strings by scanning through the entire data source to locate only those data strings that satisfy the following requirements:
   i. it contains a data point with the same type as the selected data point type, and
   ii. it contains a data point with the same type as the selected X-group-by data point, and
   iii. it contains a data point with the same type as the selected Y-group-by data point, and
   iv. its timestamp value is within the selected date/time range, and
   v. all include_only_if_filters are true.
l. processing each individual data string in the said subset as follows:
   i. setting the current data point value to the value of the selected data point type from the individual data string, and
   ii. setting the current Y-group-by value to the value of the selected Y-group-by data point type from the individual data string, and
   iii. setting the current X-group-by value to the value of the selected X-group-by data point type from the individual data string, and
   iv. selecting the row in the 2D-table with label equal to the current Y-group-by value, or if not existent, inserting into the 2D-table a new row with zero numerical values and label equal to current Y-group-by value then using the new row as the selected row, and
   v. selecting the column in the 2D-table with label equal to the current X-group-by value, or if not existent, inserting into the 2D-table a new column with zero numerical values and label equal to the current X-group-by value then using the new column as the selected column, and
   vi. selecting the cell in the 2D-table processing same indices as the index of the selected row and the index of the selected column, and
   vii. updating the selected cell value by performing a math operation related to the selected math operation on the selected cell value using the current data point value.
m. performing, as required, additional math operations on each cell of the 2D-table to complete the selected math operation, and
n. providing the said 2D-table with its labeled rows and columns as the pivot table report to the requesting party.

Data at the network server 30 may comprise an energy import configuration string containing information indicating whether or not an ampere sampling channel is connected to an AC electrical load that always imports energy and never exports energy, and a graphical user interface to create and modify said string. The network server data may further include a sampling channel to breaker pole lookup table comprising at least one sampling channel ID and breaker pole ID pair. For each ampere sensor connected to a sampling channel, the sampling channel ID is paired with the ID number of a breaker pole, such that the conductor to which the ampere sensor is connected is the same conductor connected to the breaker pole of the corresponding breaker pole ID. For sampling channels not connected to an ampere sensor, the sampling channel ID is paired with the value zero. A graphical user interface is provided to create and modify the lookup table. The network server data may further include a breaker pole to voltage phase element lookup table, comprising at least one breaker pole ID and voltage phase element ID pair, the ID number of the breaker pole being paired with the ID (e.g. A, B or C) of the voltage phase element to which the breaker pole is attached. The network server 30 may be further configured, upon receiving such a request from a nodal junction controller, to transmit an energy import configuration string to a nodal junction 20, and/or to transmit a sampling channel to breaker pole lookup table to a nodal junction 20, and/or to transmit a breaker pole to voltage phase element lookup table to a nodal junction 20.

The network server 30 may be programmed to compute the DFT coefficients, representative of the magnitudes and phase shifts of the fundamental and harmonic frequencies, by performing a Fast Fourier Transform on received arrays of digital samples.

In the preferred embodiments the network server may store a sampling channel to breaker pole lookup table comprising at least one sampling channel ID and breaker pole ID pair, wherein for each ampere sensor connected to a sampling channel the sampling channel ID is paired with the ID of a breaker pole, such that the conductor to which said ampere sensor is connected is the same conductor connected to that said breaker pole. For sampling channels not connected to an ampere sensor, the sampling channel ID is paired with the value zero. A graphical user interface can be provided to create and modify this lookup table. Similarly, the network server may store a breaker pole to AC electrical load lookup table comprising at least one breaker pole ID and AC electrical load ID pair, wherein for each breaker pole and the AC electrical load to which it is attached, the ID of the breaker pole being paired with the ID of the said AC electrical load. A graphical user interface can be provided to create and modify the lookup table.

Other graphical user interfaces may include a graphical user interface to create and modify at least one expected baseline of electrical measurements values, a graphical user interface to create and modify at least one expected baseline of DFT coefficients, a graphical user interface to create and modify at least one historic baseline of electrical measurements values by querying stored electrical values, and/or a graphical user interface to create and modify at least one historic baseline of DFT coefficients by querying stored DFT coefficients.

The network server 30 may be configured to extract electrical measurements, timestamps and sampling channel IDs from received data strings, to extract arrays of digital samples, timestamps and sampling channel IDs from received data strings, and to determine which breaker pole ID received data is associated with by querying the sampling channel to breaker pole lookup table using the sampling channel ID of the received data. The received data may comprise any of an electrical measurement, an array of digital samples, and/or a set of DFT coefficients. The network server 30 may be further configured to determine which AC electrical load ID received data is associated with, by querying the breaker pole to AC electrical load lookup table using the breaker pole ID of said received data, The network server 30 may store electrical measurements, arrays of digital samples and sets of DFT coefficients along with associated timestamps, sampling channel IDs, breaker pole IDs and AC electrical load IDs into a database for further analysis, perform data queries and compute aggregate operations on the electrical measurements for at least one AC electrical load, compare real time electrical measurements and real time DFT coefficients with values from at least one expected baseline or from at least one historic baseline and to notify personal of meaningful variations and analyze stored electrical measurements and DFT coefficients in order to identify changes over time.

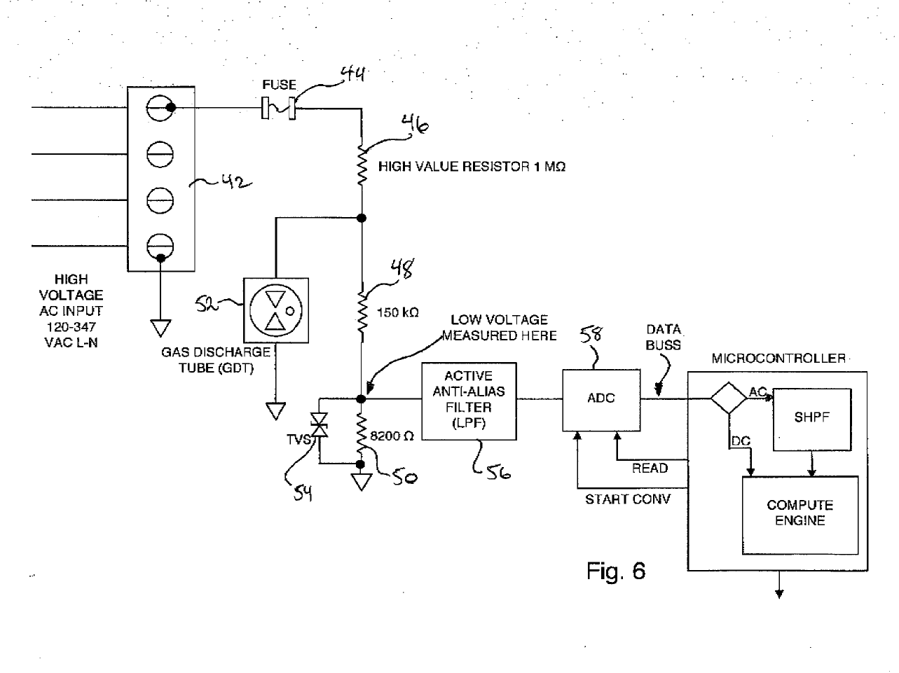

FIG. 6 illustrates an embodiment of a voltage sensor circuit 40, which in the preferred embodiment comprises certain safety features to limit the mains supply voltage applied to the sensing circuitry in the event of a fault condition. In the example shown the sensor circuit 40 is connected to phase A of high voltage terminal block 42. A suitably rated fuse 44 is the primary overcurrent protection for the circuit 40. Fuse 44 is connected to a grounded series resistor network comprising a high voltage resistor 46 having a resistance of 1000 kΩ, resistor 48 having a resistance of 150 kΩ and resistor 50 having a resistance of 8200Ω. A tap between resistors 46 and 48 is connected to a grounded gas discharge tube 52 which serves to blow fuse 44 in the event of a short circuit fault of resistor 46. Additionally, a tap between resistors 48 and 50 is connected to a grounded transient voltage suppressor 54, further protecting the circuit 40 from transient overvoltages, for example caused by electrostatic discharge or other transient fault conditions (in the order of milliseconds).

A low voltage signal proportional to the mains voltage is tapped from the output end of resistor 48 and fed to a low pass filter 56 directly wired to the sensor 12, preferably an active multi-pole antialiasing filter, to prepare the low voltage signal for digitization. The low voltage signal is quantized via analog to digital converter (ADC) 58 and fed to microcontroller 60 and optionally passed through a high pass filter implemented in software to eliminate any DC component of the AC signal so that calculations performed by the microprocessor exclude the DC component. The resulting calculations are output from the microcontroller 60, in the preferred embodiment to the communications module 22 which transmits derived data to the network server 30, for example in an IP or other network protocol, to the network server 30 for storage in a local data store.

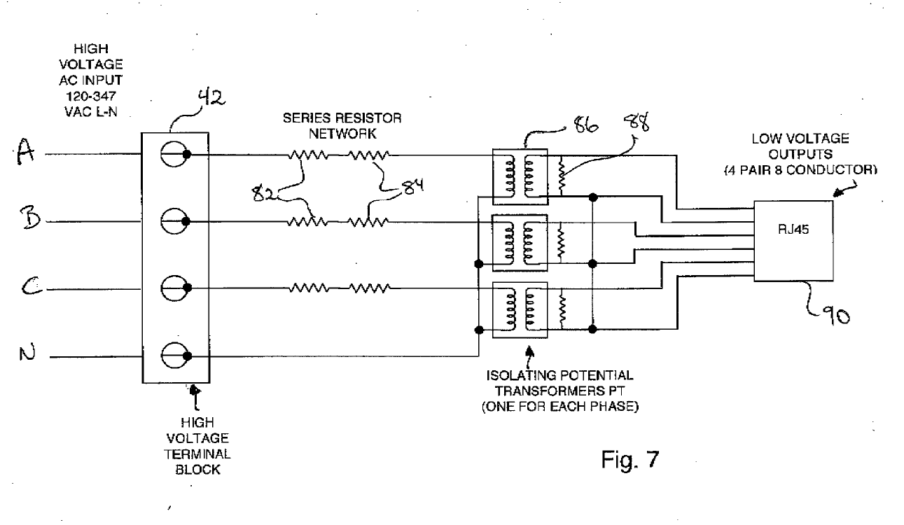

FIG. 7 illustrates a voltage sensor circuit 70 using potential transformers 76 to isolate the mains supply voltage from the sensing circuitry in the event of a fault condition. In the example shown separate sensor circuits 80 are respectively connected to phases A, B and C of high voltage terminal block 42. The high voltage mains supply signal is fed to a series resistor network comprising at least two high voltage resistors 82 and 84, each having a resistance determined by the maximum rating of the potential transformer 86. At least two resistors 82, 84 are preferred, each serving as a backup in the event of the failure of the other resistor 82 or 84 to prevent a high current from reaching the potential transformer 86. This also has the advantage of permitting more efficient heat dissipation.

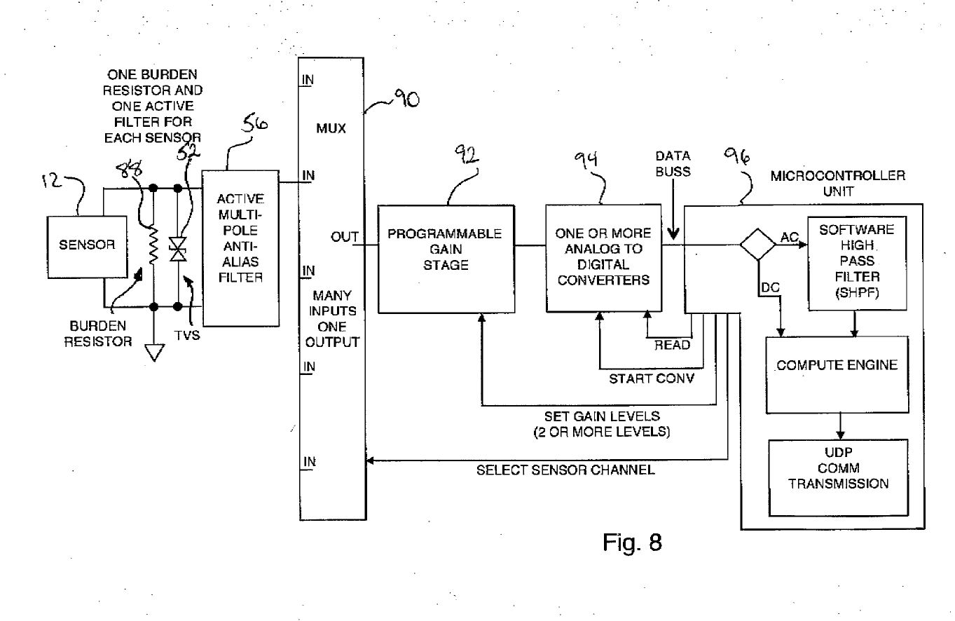

The potential transformers 86 isolate the system of the invention from fault conditions resulting in high voltage differences across the primary and secondary of the potential transformer 86, without affecting the linearly scaled down proportionality of the sensor output to the conductor 2 during normal operation, i.e. absent a fault condition. A burden resistor 88 shunts the outputs from the potential transformers 86, and provides an acceptable level of burden to the output of current transformer 22 while maintaining the normal voltage and thus the secondary of the potential transformer to Class 2 voltage levels. However, in the event of a momentary fault which energizes either conductor 22b with the higher Class 1 mains voltage, the isolation provided by the potential transformers provide a level of protection against damage to the downstream system components. An example of a system utilizing potential transformers 86 to isolate the sensors from downstream circuitry is described and illustrated in co-pending Canadian patent application no. 2,832,237 filed Nov. 7, 2013 by the present applicant, which is incorporated herein by reference in it's entirety. The outputs of the potential transformer 86 are connected to a suitable coupler, for example an RJ45 connector as shown, which transmits the proportional low voltage output of the sensor circuit 70 to the system input, for example filter 56 shown in FIGS. 6 and 8.

Each nodal junction 20 may comprise at least one active anti-aliasing low pass filter circuit 56 connected to a sampling channel, the filter circuit comprising one or more poles; and a programmable gain stage providing at least one level of gain under software control. At least one multiplexer circuit capable of routing signals from one of several sampling channels to the input of the programmable gain stage circuit (or optionally to the input of an analog to digital converter circuit, not shown). The ADC output may be processed by a high pass filter, for example implemented in software in the microcontroller, the software filter being configured to minimize the DC offset errors in the digital samples from the sampling channel that are introduced by non-ideal characteristics of various hardware circuits over various operating conditions. FIG. 8 for example illustrates a further embodiment of the sensing circuitry wherein the outputs of the sensor 12 are connected to an active multi-pole antialiasing filter 56, which in turn transmits the proportional low voltage signal to a many-to-one multiplexer (MUX) 90. A plurality of sensors/filters are connected to the various inputs of the MUX 90, which creates a plurality of sensor sampling channels. Microcontroller 96 selects one sensor sampling channel for output to the programmable gain module 92, the gain through which is set by microcontroller 96 based on the sensed voltage level of the filters proportional low voltage signal from the sensor. For example, one sensor 12 may be monitoring a circuit with an active high-current load such as a clothes dryer, which results in a proportional low voltage sensor output that is still fairly substantial, while another sensor 12 may be monitoring a circuit with only low-current loads such as digital devices, which results in a proportional low voltage sensor output that is too low to be accurately monitored. In the latter case microcontroller 96, having selected a sensor output for sampling, detects the voltage level of the MUX output and tasks programmable gain module 92 to boost the MUX output to a level more suitable for sampling. The output of programmable gain module 92 is fed to analog-to-digital converter (ADC) 94 and the quantized output of ADC 94 is fed to the microcontroller for packetization for transmission, for example in an IP or other network protocol, to the network server 30 for storage in a local data store. An internal thermometer circuit may be provided to measure the temperature of the various circuits with the nodal junction 20.

In some embodiments each nodal junction 20 may be configured to provide voltage sampling channels, each sampling a voltage sensor output associated with each voltage phase element, which can be identified uniquely by the ID (e.g. A, B or C) of the voltage phase element to which the voltage sensor is attached. Other available sampling channels can be assigned as ampere sampling channels and connected to ampere sensors. The nodal junction 20 can sequentially perform sampling on a subset of its sampling channels using one of its analog to digital converter circuits in combination with a multiplexer circuit and/or a programmable gain stage circuit. Alternatively, the nodal junction 20 can simultaneously perform sequential sampling on multiple subsets of its sampling channels using a separate analog to digital converter circuit for each such subset, and create arrays of digital samples where each such array sampled from any one of the nodal junction sampling channels is representative of a single AC waveform or a time interval.

The nodal junction 20 may be programmed to request a sampling channel to breaker pole lookup table from a network server 20, and/or to request a breaker pole to voltage phase element lookup table from a network server 20. In the preferred embodiment the nodal junction microcontroller 60 performs calculations prior to transmission of data to the network server, for example computing the root mean square (rms) values of arrays of digital samples. The nodal junction microcontroller 60 may make computations utilizing calibration scaling factors, one such factor for each sampling channel. Similarly the nodal junction microcontroller 60 may compute voltage measurements using an rms value and a scaling factor, one such measurement for each attached voltage sensor, and/or compute amperage measurements using an rms value and a scaling factor, one such measurement for each attached ampere sensor. The nodal junction microcontroller 60 would associate each ampere sampling channel with one voltage sampling channel by using the ID of the ampere sampling channel and the sampling channel to breaker pole lookup table to determine the breaker pole ID, and then by using the breaker pole ID and breaker pole to voltage phase element lookup table to determine the voltage phase element ID, and then by using the breaker pole ID to identify the voltage sampling channel. The permits the nodal junction microcontroller 60 to compute the instantaneous real power associated with an ampere sampling channel by the mathematical product of sampled ampere values with its associated sampled voltage values, and then by applying the associated ampere and voltage scaling factors. The nodal junction microcontroller 60 is preferably also able to compute the real power associated with an ampere sampling channel by first computing the average value of the instantaneous real power over at least one complete AC wave form, and then by applying the associated ampere and voltage scaling factors; and to compute the energy transfer associated with an ampere sampling channel by integrating over time the instantaneous real power mathematical product of sampled ampere values with its associated sampled voltage values. The nodal junction microcontroller 60 may store all electrical measurements in a non-volatile memory and/or in a volatile memory. Such electrical measurements may comprise ampere values, voltage values, power values, energy values, and/or other related values.

The nodal junction microcontroller 60 preferably associates each stored electrical measurement with a timestamp identifying when the measurement was computed, and with the sampling channel ID from which it was computed. The nodal junction microcontroller 60 preferably similarly associates each array of digital samples with a timestamp identifying when it was collected and with the sampling channel ID from which it was collected. The nodal junction microcontroller 60 can request an energy import configuration string from a network server, and use such a string to automatically change the sign of any power or energy measurement that has a negative value (for example, as a result of an ampere sensor being installed backwards) when the information in such a string indicates that such measurements must always be non-zero, and can adjust the accuracy of electrical measurements by using the internal thermometer circuit and a temperature calibration table. The nodal junction microcontroller 60 creates data strings comprising the nodal junction microcontroller 60 ID (e.g. serial number) and either or both of the electrical measurements, their timestamps and sampling channel ID; and arrays of digital samples, their timestamps and sampling channel ID. This data is preferably continuously transmitted in data strings to the network server 30 at selected fixed intervals.

The nodal junction 20 may further comprise one or more hardwired internal voltage sensor circuits (see FIG. 6), each such circuit having a dedicated sampling channel and analog to digital convertor circuit.

Various embodiments of the present invention having been thus described in detail by way of example, it will be apparent to those skilled in the art that variations and modifications may be made without departing from the invention. The invention includes all such variations and modifications as fall within the scope of the appended claims.

We claim:

1. A system for monitoring electrical variables of at least one AC electrical load wired to at least one breaker pole connected to a phase of an AC electrical source, comprising
at least one ampere sensor configured to produce an output analog signal proportional to the amperes in at least one electrical load conductor, comprising an inductor having at least one complete electrical turn in inductive communication with said load conductor,
at least one nodal junction configured to calculate at least one electrical measurement from the signal received from the at least one sensor, and configured to create at least one data string comprising at least one electrical measurement, and a network communication circuit configured to transmit data to a network server, and
at least one network server configured to receive data strings from the at least one nodal junction controller, to transmit a reply data string to the at least one nodal junction controller for each set of one or more data strings received, each reply string containing acknowledgement data for the set of one or more data strings to which the reply relates, and optionally data to control and change the functionality of the at least one nodal junction controller via an optional command string returned with said reply string.

2. The system of claim 1 further comprising at least one voltage sensor configured to produce an output analog signal proportional to the voltage difference between one voltage phase element and a reference point common to all voltage phase elements.

3. The system of claim 1 wherein the nodal junction further comprises at least one microcontroller, at least one timer circuit, at least one analog to digital converter, at least one volatile memory, at least one non-volatile memory, at least one sampling channel comprising a unique sampling channel ID for connection to at least one sensor.

4. The system of claim 1 wherein the reply data string comprises acknowledgement data comprising of a hash string number of the data string to which the reply relates.

5. The system of claim 3 wherein each nodal junction further comprises one or more of an active anti-aliasing low pass filter circuit, a programmable gain stage circuit connected to the input of an digital converter, a multiplexer circuit capable of routing signals from one of several sampling channels to either the input of the programmable gain stage circuit or to the input of an analog to digital converter circuit, and a high pass filter configured to minimize the DC offset errors in digital samples from any sampling channel, and an internal thermometer circuit used measure the temperature of one or more of the circuits with the nodal junction.

6. The system of claim 1 wherein the nodal junction is configured to change its functionality upon receipt and interpretation of its command string from the network server.

7. The system of claim 1 further comprising at least one sensor designed to provide at least one signal representative of a non-electrical measurement.

8. The system of claim 1 wherein the network server is further configured to access to at least one remote database containing weather information for at least one geographic region.

9. The system of claim 1 wherein the network server further comprises at least one password-protected application programmers interface configured to enable third parties to query the local data store.

10. The system claim of claim 1 wherein the network server, or the at least one nodal junction upon command from the network server is configured to compute DFT coefficients representative of the magnitudes and phase shifts of the fundamental and harmonic frequencies of a monitored signal by performing a Fast Fourier Transform on arrays of digital samples.

11. The system of claim 1 wherein the network server is configured to initiate one or more notifications based on one or more logical combinations of one or more electrical measurements and/or DFT coefficients based on configurable thresholds.

12. A method for securely collecting and storing electrical variables associated with at least one AC electrical load or electrical power source, comprising the steps of:
a. receiving a signal from at least one sensor having inputs connected to a supply circuit conductor of the AC electrical load or source,
b. calculating at least one electrical measurement derivable from the at least one sensor,
c. providing an encryption algorithm and a encryption key for encrypting the at least one electrical measurement, and
d. encrypting and transmitting the at least one electrical measurement to a network server accessible by one or more parties possessing said encryption key.

13. The method of claim 12 wherein received data strings are appended to individual flat files stored within the network server.

14. The method of claim 13 wherein the network server is configured to permit third parties to download flat files using an application programmers interface.

15. A method for analyzing electrical measurements from AC electrical loads or AC electrical sources comprising the steps of:
a. receiving a signal from at least one sensor having inputs connected to a supply circuit conductor of at least one of the AC electrical load or the AC electrical source, or both,
b. calculating electrical measurements derivable from the signal received from the at least one sensor,
c. storing said electrical measurements in a data store in association with respective timestamps,
d. querying said electrical measurements along with data from at least one external source comprising one or more of:
weather data;
data representing the percentage that the amount of electrical energy relating to the electrical energy measurements is to all electrical energy produced from electrical energy sources; and
data representing amounts of greenhouse gases released into the atmosphere for each Watt Hour of electrical energy produced from said energy sources, and
e. displaying the results in the form of a pivot table report.

16. The method of claim 15 wherein step e. also comprises querying said electrical measurements along with measurement data stored in at least one local data store comprising one or more of pre-existing electrical measurement data, building structure data, equipment data and occupancy data.

17. The method claim of claim 15 wherein the network server, or the at least one nodal junction upon command from the network server is configured to compute DFT coefficients representative of the magnitudes and phase shifts of the fundamental and harmonic frequencies of a monitored signal by performing a Fast Fourier Transform on arrays of digital samples.

18. The method of claim 15 wherein the network server is configured to initiate one or more notifications based on one or more logical combinations of one or more electrical measurements and/or DFT coefficients based on configurable thresholds.
